(19) United States
(12) Patent Application Publication
(10) Pub. No.: US 2025/0089343 A1
(43) Pub. Date: Mar. 13, 2025

(54) POWER SEMICONDUCTOR DEVICE INCLUDING SILICON CARBIDE (SIC) SEMICONDUCTOR BODY

(71) Applicant: Infineon Technologies AG, Neubiberg (DE)

(72) Inventors: Andreas HÜRNER, Heroldsberg (DE); Michael HELL, Erlangen (DE); Thomas AICHINGER, Faak am See (AT)

(21) Appl. No.: 18/824,073

(22) Filed: Sep. 4, 2024

(30) Foreign Application Priority Data
Sep. 12, 2023 (DE) 102023124600.3

(51) Int. Cl. H01L 29/51; H01L 29/16; H01L 29/423; H01L 29/66; H01L 29/78

(52) U.S. Cl. CPC H10D 64/683; H10D 12/031; H10D 30/668; H10D 30/699; H10D 62/8325; H10D 64/691; H10D 84/143

(57) ABSTRACT

A power semiconductor device is proposed. The power semiconductor device includes a silicon carbide (SiC) semiconductor body having a first surface and a second surface opposite to the first surface. The SiC semiconductor body includes a transistor cell area comprising transistor cells. Each of the transistor cells includes a gate structure including a gate dielectric structure and a gate electrode structure on the gate dielectric structure. The gate dielectric structure includes a first gate dielectric layer adjoining to the SiC semiconductor body. The gate dielectric structure further includes a second gate dielectric layer. The gate dielectric structure further includes charge storage layer arranged between the first gate dielectric layer and the second gate dielectric layer.

### RELATED APPLICATION

This application claims priority to German Patent Application No. 102023124600.3, filed on Sep. 12, 2023, entitled “POWER SEMICONDUCTOR DEVICE INCLUDING SIC SEMICONDUCTOR BODY”, which is incorporated by reference herein in its entirety.

### TECHNICAL FIELD

The present disclosure is related to a power semiconductor device, in particular to a power semiconductor device including a silicon carbide (SiC) semiconductor body.

### BACKGROUND

Technology development of new generations of silicon carbide (SiC) power semiconductor devices, e.g. insulated gate field effect transistors (IGFETs) such as metal oxide semiconductor field effect transistors (MOSFETs) or insulated gate bipolar transistors (IGBTs), aims at improving electric device characteristics such as the short-circuit current capability. A variety of tradeoffs and challenges have to be met when improving the short-circuit current capability of a SiC power semiconductor device. For example, improving the short-circuit current capability, e.g. by reducing the saturation current by lower overdrive voltages, and/or by higher threshold voltages Vth, and/or by lower gate voltages, and/or by longer MOS channels, may have a negative impact on the overall device performance or may increase circuit complexity.

There is a need for improving the short-circuit current capability of SiC power semiconductor devices.

### SUMMARY

An example of the present disclosure relates to a power semiconductor device. The power semiconductor device includes a silicon carbide (SIC) semiconductor body having a first surface and a second surface opposite to the first surface. The SiC semiconductor body includes a transistor cell area including transistor cells. Each of the transistor cells includes a gate structure including a gate dielectric structure and a gate electrode structure on the gate dielectric structure. The gate dielectric structure includes a first gate dielectric layer adjoining to the SiC semiconductor body, a second gate dielectric layer, and a charge storage layer arranged between the first gate dielectric layer and the second gate dielectric layer.

Another example of the present disclosure relates to a method of manufacturing a power semiconductor device. The method incudes providing a silicon carbide (SiC) semiconductor body having a first surface and a second surface opposite to the first surface. The method further includes forming a transistor cell area comprising transistor cell in the SiC semiconductor body. Each of the transistor cells includes a gate structure including a gate dielectric structure and a gate electrode structure on the gate dielectric structure. The gate dielectric structure includes a first gate dielectric layer adjoining to the SiC semiconductor body, a second gate dielectric layer, and a charge storage layer arranged between the first gate dielectric layer and the second gate dielectric layer.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of silicon carbide (SiC) power semiconductor devices and together with the description serve to explain principles of the embodiments. Further embodiments are described in the following detailed description and the claims.

FIG. 1A schematically and exemplarily shows a partial cross-sectional view of a configuration example of a SiC power semiconductor device including a planar gate structure.

FIG. 1B schematically and exemplarily shows a partial cross-sectional view of a configuration example of a SiC power semiconductor device including a trench gate structure.

FIG. 2 schematically and exemplarily shows a partial cross-sectional view of a configuration example of a SiC power MOSFET including a trench gate structure.

FIGS. 3A to 3C are schematic views for illustrating operation modes of a configuration example of a power MOSFET.

FIGS. 4A to 7 are schematic band diagrams for illustrating operation modes of configuration examples of a power MOSFET.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this may be understood to disclose all possible combinations, i.e. only A, only B as well as A and B, if not explicitly or implicitly defined otherwise. An alternative wording for the same combinations may be “at least one of A and B” or “A and/or B”. The same applies, mutatis mutandis, for combinations of more than two elements.

Ranges given for physical dimensions may include the boundary values. For example, a range for a parameter y from a to b reads as a≤y≤b. The same holds for ranges with one boundary value like “at most” and “at least”.

Main constituents of a layer or a structure from a chemical compound or alloy may be such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

An example a power semiconductor device includes a silicon carbide, SiC, semiconductor body having a first surface and a second surface opposite to the first surface. The SiC semiconductor body may include a transistor cell area comprising transistor cells. Each of the transistor cells may include a gate structure including a gate dielectric structure and a gate electrode structure on the gate dielectric structure. The gate dielectric structure may include a first gate dielectric layer adjoining to the SiC semiconductor body. The gate dielectric structure may further include a second gate dielectric layer. The gate dielectric structure may further include a charge storage layer arranged between the first gate dielectric layer and the second gate dielectric layer.

The power semiconductor device may be part of an integrated circuit or may be a discrete semiconductor device or a semiconductor module, for example. The power semiconductor device may be or may include an insulated gate field effect transistor (IGFET) such as a metal oxide semiconductor field effect transistor (MOSFET) or an insulated gate bipolar transistor (IGBT), for example. The power semiconductor device may be a vertical power semiconductor device having a load current flow between the first surface and the second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The power semiconductor device may be based on a semiconductor body from a crystalline SiC semiconductor material having a band gap larger than the band gap of silicon, i.e. larger than 1.12 eV. For example, the semiconductor material may be 2H—SiC (SiC of the 2H polytype), 6H—SIC or 15R—SiC. According to an example, the semiconductor material is silicon carbide of the 4H polytype (4H—SiC). The semiconductor body may include or consist of a semiconductor substrate having none, one or more than one semiconductor layers, e.g. epitaxially grown layers, thereon.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

For realizing a desired current carrying capacity, the SiC power semiconductor device may be designed by a plurality of parallel-connected transistor cells. The parallel-connected transistor cells may, for example, be transistor cells formed in the shape of a strip or a strip segment. Of course, the transistor cells can also have any other shape, e.g. circular, elliptical, polygonal such as hexagonal or octahedral. The transistor cells are arranged in the transistor cell area of the SiC semiconductor body. The transistor cell area may be an active area where an emitter region of an IGBT (or a source region of a MOSFET) and a collector region of an IGBT (or a drain region of a MOSFET) are arranged opposite to one another along the vertical direction. In the active area, a load current may enter or exit the semiconductor body of the power semiconductor device, e.g. via contact plugs on the first surface of the SiC semiconductor body. The power semiconductor device may further include an edge termination area that may include a termination structure. In a blocking mode or in a reverse biased mode of the power semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

For example, the gate structure may be a planar gate structure, or may be a trench gate structure. The gate structure may be the stripe-shaped. The gate electrode structure may also have another layout or geometry in a plan view, e.g. hexagonal, square, circular, elliptic. The gate electrode structure of the gate structure may be electrically connected to a gate pad via a gate interconnection structure, for example. The gate interconnection structure or a part thereof may be arranged outside of the transistor cell area may be arranged laterally between the transistor cell area and the edge termination area. The interconnection electrode may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. At least part of the interconnection electrode may be a so-called gate runner that merges with the gate pad. The gate pad and, for example, a first load electrode pad, e.g. a source pad of a MOSFET or an emitter pad of an IGBT, may be part of a wiring area over the wide band gap semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) and/or contact line(s) may be formed in openings of the interlayer dielectric structure to electrically connect parts, e.g. metal lines or contact areas, of different wiring levels to one another.

By providing the charge storage layer in the gate dielectric structure, an intermediate insulating layer may be integrated into the gate dielectric structure, i.e. between first gate dielectric layer and the second gate dielectric layer. The charge storage layer, e.g. an interlayer, may be configured to trap charges depending on the operating state of the power semiconductor device. For example, in a normal operation state or mode of the power semiconductor device, this interlayer may be uncharged. In the case of a short-circuit current event, charges, e.g. electrons, may be injected into this interlayer from the channel region of the power semiconductor device and form a charge QOX on this interlayer. This charging process may be caused by, for example, a temperature rise within the power semiconductor device. The temperature rise may be due to a short-circuit current event, for example. In case of an n-channel power semiconductor device, this may increase the negative electron charge on the interlayer and thus the threshold voltage of the power semiconductor device. Consequently, this may lead to a reduction of the so-called overdrive voltage. The saturation current and thus the thermal load in the short-circuit case may likewise decrease. When appropriately designing the power semiconductor device, a complete turn-off of the power semiconductor device may be achieved. Technical effects and benefits associated with the configuration examples of power semiconductor devices disclosed herein include one or more of, inter alia:
a self-triggering turn-off or shutdown of the short circuit may allow for avoiding a significant thermal load of the power semiconductor device without influencing device parameters. This may also allow the use of gate materials that are sensitive to elevated temperatures (e.g. high-k dielectric materials);
optimization of the short-circuit strength or short-circuit current capability of the power semiconductor device may be carried out independently of the optimization of other important electrical properties (e.g. channel density, JFET, dual-gate);
no further circuitry may be required for monitoring, detection and disconnection of the short circuit. This may reduce the complexity of the overall system and, above all, transfers the added value of these functions to the power semiconductor device;
after the power semiconductor device has switched itself off by self-triggering and the the cause of the short-circuit in the overall system has been eliminated, the threshold voltage may be restored to or close to its original state, e.g. by selectively applying a negative gate voltage.

For example, a conduction band offset at a first interface between the SiC semiconductor body and the first dielectric layer may have a value in a range from 1.0 eV to 2.0 eV, or from 1.5 eV to 2.0 eV. This may be achieved by an appropriate material for the first dielectric layer. The conduction band offset range from 1.0 eV to 2.0 eV, or from 1.5 eV to 2.0 eV, may allow for, based on thermionic emission described by Richardson's law, accumulating a charge in the charge storage layer that allows to turn-off the power semiconductor device in an appropriate time period based on the shift in the threshold voltage by the charging process.

For example, the gate dielectric structure may further include a third gate dielectric layer arranged between the second gate dielectric layer and the gate electrode. The third gate dielectric layer may adjoin to the gate electrode. Provision of the third gate dielectric layer may allow for optimizing the second gate dielectric layer with respect to charge trapping in the charge storage layer on the one hand, e.g. by appropriately setting a band offset between the charge storage layer and the second dielectric layer, and by optimizing the third gate dielectric layer with respect to the contact with the termination of the gate dielectric structure toward the gate electrode structure on the other hand.

For example, the third gate dielectric layer may be a high-k dielectric layer. For example, a high-k dielectric material in the third gate dielectric layer or any other high-k dielectric layer of the gate dielectric structure may include at least one of Al₂O₃, ZrO₂, HfO₂, AlN, aluminosilicate AlSiOₓ, silicon doped HfO₂, lanthanum doped HfO₂, TiO₂, Y₂O₃ or Si₃N₄, ONO (oxide-nitride-oxide), or any stacked combination thereof.

For example, the second gate dielectric layer may adjoin to the gate electrode. This may allow for providing a gate dielectric structure including a charge storage layer for self-triggering turn-off that can be easily manufactured by including a minimum of dielectric sub-layers.

For example, the charge storage layer may include a potential well for electrons. A conduction band offset at a second interface between the charge storage layer and the first gate dielectric layer may be smaller than a conduction band offset at a third interface between the charge storage layer and the second gate dielectric layer. This may allow for avoiding a transfer of the trapped charges, e.g. electrons, from the charge storage layer to the gate electrode structure.

For example, a difference between the conduction band offset at the third interface and the conduction band offset at the second interface may have value in a range from 0.5 eV to 3 eV.

For example, the conduction band offset at the second interface may have a value in a range from 0.5 eV to 1.5 eV.

For example, the charge storage layer may be a Hf₂O₃ layer. The first gate dielectric layer may be an Al₂O₃ layer. The second gate dielectric layer may be a SiO₂ layer. Thereby, a potential well for electrons may be achieved that has a larger band offset toward the gate electrode structure than toward the SiC semiconductor body. This may allow for avoiding a transfer of the trapped charges, e.g. electrons, from the charge storage layer to the gate electrode structure.

For example, the charge storage layer may be an interface layer comprising interface trap states at an interface between the first gate dielectric layer and the second gate dielectric layer. A surface treatment process of the first gate dielectric layer before formation, e.g. deposition, of the second gate dielectric layer on the treated surface, may allow for setting an interface trap density, for example. A surface treatment process of the first gate dielectric layer before formation, e.g. deposition, of the second gate dielectric layer on the treated surface, may allow for reducing the trap density at the interface between the first gate dielectric layer and the SiC semiconductor. After the first gate dielectric layer was annealed, the second dielectric layer is deposited. For example, materials of the first and second gate dielectric layers may correspond to one another.

For example, the charge storage layer may be a transition gate dielectric layer having a material composition that changes, along a thickness direction of the gate dielectric structure, from the material composition of the first gate dielectric layer to the material composition of the second gate dielectric layer. According to a configuration example, the transition gate dielectric layer may transition from a material composition of Al₂O₃ (first gate dielectric layer) to a material composition of SiO₂ (second gate dielectric layer). According to another configuration example, the transition gate dielectric layer may transition from a material composition of AlₓSiO_{y} (first gate dielectric layer) to a material composition of SiO₂ (second gate dielectric layer). According to another configuration example, the transition gate dielectric layer may transition from a material composition of AlN (first gate dielectric layer) to a material composition of Al₂O₃ (second gate dielectric layer). According to yet another configuration example, the transition gate dielectric layer may transition from a material composition of HfO₂ (first gate dielectric layer) to a material composition of SiO₂ (second gate dielectric layer).

For example, a thickness of the transition gate dielectric layer may have a value in a range from 0.1 nm to 3 nm.

For example, the transition gate dielectric layer may include a concentration of impurities having a value in a range from 10¹¹ cm⁻³ to 10¹³ cm⁻³. The impurities may be configured as acceptor-like states within the dielectric bandgap, for example.

For example, a thickness of the first gate dielectric has a value in a range from 3 nm to 20 nm. When reducing the thickness of the first gate dielectric below the lower limit, undesired direct tunneling of electrons from the channel into the charge electrode layer becomes more likely. When increasing the thickness of the first gate dielectric above the upper limit, the effect on shifting the threshold voltage Vth may be too low.

For example, the power semiconductor device may be an n-channel vertical power MOSFET (or IGBT) comprising a gate trench including the gate structure.

For example, the vertical power MOSFET may include a p-doped diode region adjoining to one sidewall of opposite first and second sidewalls of the gate trench. The p-doped diode region may also adjoin to a bottom side of the gate trench. The p-doped diode region may be configured to shield the gate dielectric structure at a bottom side of the gate trench from high electric field strengths, for example. The one sidewall adjoining to the p-doped diode region may define a non-channel region of the vertical power MOSFET. The other sidewall of the gate trench may define a channel region formed by a part of a p-doped body region that adjoins to the gate structure at the other sidewall of the gate trench. For example, a conductivity of the channel region may be controlled by a potential applied to the gate electrode structure, e.g. by field effect. For example, a positive voltage applied to the gate electrode structure in an n-channel MOSFET may induce an n-inversion channel in part of the p-doped body region adjoining the first gate dielectric layer, for example. The body region may be electrically connected via the first surface, e.g. by a contact plug on a top surface of the body region and/or a groove contact that may extend into the SiC semiconductor body and may be electrically connected to the body region via a sidewall of the groove contact. The channel region part of the body region may include a partial compensation by dopants of the second conductivity type, e.g. n-type dopants in case of a p-doped body region, for adjusting the threshold voltage, for example. The partial compensation may be achieved by a tilted ion implantation through a sidewall of a trench, for example. For example, sidewalls of the gate trench may be non-tapered or slightly tapered. In case of slightly tapered sidewalls of the gate trench, a channel length may be slightly larger than the vertical extent of a channel region. The taper angle of the trench gate structure may be caused by process technology, e.g. aspect ratio of trench etch processes, and may also be used for maximizing the charge carrier mobility in the channel region which depends from the direction along which channel current flows. Another example for a tapered trench gate structure is a V-shaped gate trench.

An example of a method for operating the power semiconductor device of any of the configuration examples described herein includes resetting the charge storage layer of the power semiconductor device at least in part by applying a negative gate to source voltage pulse.

Details with respect to structure, or function, or technical benefit of features described above with respect to a power semiconductor device such as a FET, or IGBT likewise apply to the exemplary methods described herein. Processing the SiC semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts,-functions,-processes,-operations or -steps, respectively. Such sub acts may be included and part of the disclosure of this single act unless explicitly excluded.

A method of manufacturing a power semiconductor device includes providing a silicon carbide, SiC, semiconductor body having a first surface and a second surface opposite to the first surface. The method further includes forming a transistor cell area comprising transistor cells in the SiC semiconductor body. Each of the transistor cells includes a gate structure comprising a gate dielectric structure and a gate electrode structure on the gate dielectric structure. The gate dielectric structure may include a first gate dielectric layer adjoining to the SiC semiconductor body. The gate dielectric structure may further include a second gate dielectric layer. The gate dielectric structure may further include a charge storage layer arranged between the first gate dielectric layer and the second gate dielectric layer.

The examples and features described above and below may be combined.

Some of the above and below examples are described in connection with a silicon carbide substrate. Alternatively, a wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a silicon carbide (SiC) wafer, or gallium arsenide (GaAs) wafer, or a gallium nitride (GaN) wafer.

More details and aspects are mentioned in connection with the examples described above or below. Processing a SiC semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

In the following, further examples of field effect transistors, FETs, are explained in connection with the accompanying drawings. Functional and structural details described with respect to the examples above shall likewise apply to the exemplary embodiments illustrated in the figures and described further below. In the illustrated examples, n-channel FETs are illustrated.

However, the examples described herein may also be applied to p-channel devices, e.g. p-channel MOSFETs or p-channel IGBTs.

Details with respect to structure, or function, or technical benefit of features described above likewise apply to the examples below and vice versa.

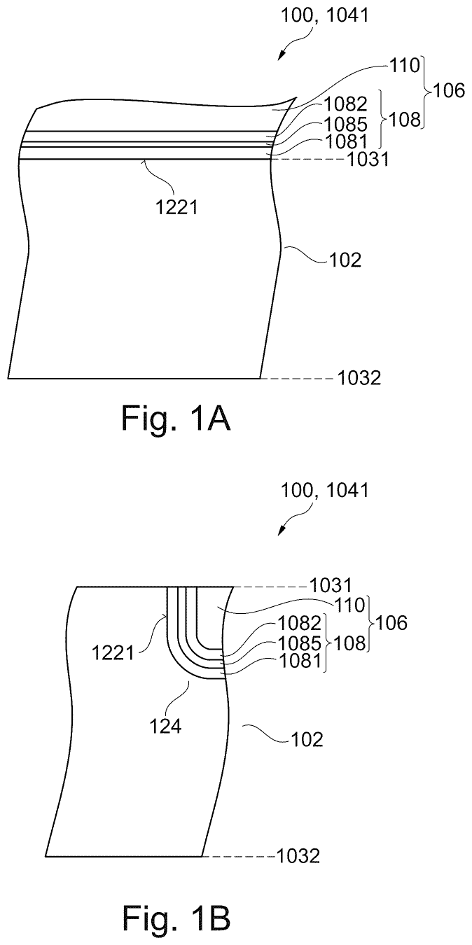

FIG. 1A schematically and exemplarily shows a partial cross-sectional view of a power semiconductor device 100 configured as a planar gate SiC power MOSFET.

The partial cross-sectional view of FIG. 1A illustrates a part of a transistor cell 1041 in a SiC semiconductor body 102 having a first surface 1031 and a second surface 1032 opposite to the first surface 1031. The SiC power MOSFET includes a gate structure 106 configured as a planar gate structure. The gate structure 106 includes a gate dielectric structure 108. A gate electrode structure 110 of the gate structure 106 is arranged on the gate dielectric structure 108. A first gate dielectric layer 1081 of the gate dielectric structure 108 adjoins to the SiC semiconductor body 102 at a first interface 1221. A charge storage layer 1085 is arranged on and adjoins to the first gate dielectric layer 1081. A second gate dielectric layer 1082 is arranged on and adjoins to the charge storage layer 1085.

FIG. 1B schematically and exemplarily shows a partial cross-sectional view of a power semiconductor device 100 configured as a trench gate SiC power MOSFET.

The partial cross-sectional view of FIG. 1B illustrates a part of a transistor cell 1041 in the SiC semiconductor body 102. The SiC power MOSFET includes the gate structure 106 configured as a trench gate structure in a gate trench 124. The gate structure 106 is configured as described with reference to FIG. 1A above.

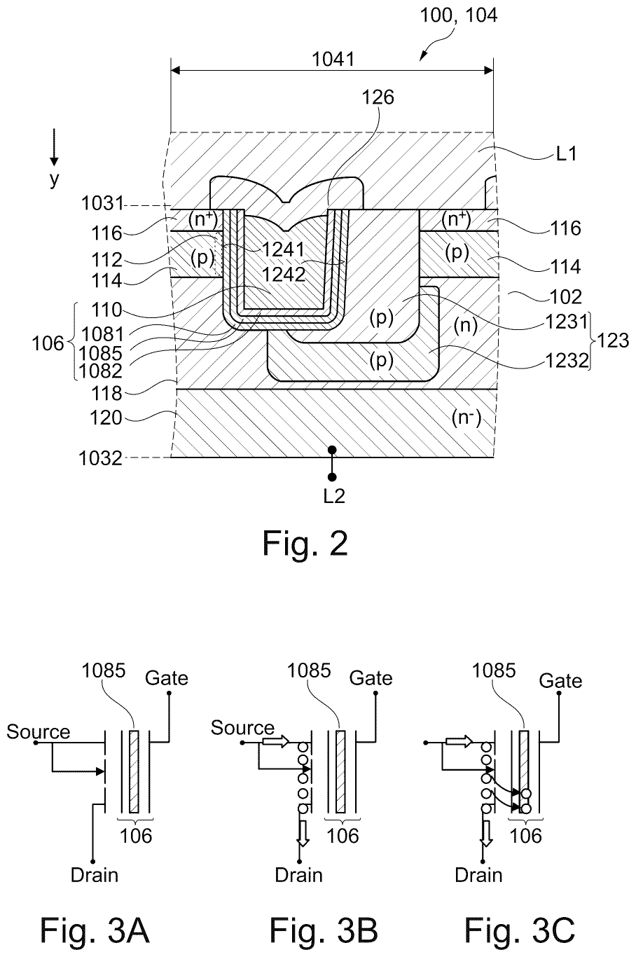

FIG. 2 schematically and exemplarily shows a partial cross-sectional view of a configuration example of a power semiconductor device 100 configured as a trench gate SiC power MOSFET. The SiC power MOSFET is a vertical power semiconductor device that further includes an edge termination area that at least partially surrounds the transistor cell area 105 (not illustrated in FIG. 2).

The gate structure 106 is configured as described above with reference to FIG. 1B. The first gate dielectric layer 1081 adjoins to a channel region 112. The channel region 112 is defined by a part of a p-doped body region 114 that adjoins to the first gate dielectric layer 1081 at a first sidewall 1241 of the gate structure 106. For example, a conductivity of the channel region 112 may be controlled by a potential applied to the gate electrode structure 110, e.g. by field effect. For example, a positive voltage applied to the gate electrode structure 110 may induce an n-type inversion channel in the channel region 112 adjoining to the first gate dielectric layer 1081, for example. The p-doped body region 114 may be electrically connected to a first load electrode L1 via the first surface 1031, e.g. by a contact plug on a top surface of the body region 114 and/or a groove contact that may extend into the SiC semiconductor body 102 and may be electrically connected to the body region 114 via a sidewall of the groove contact (not illustrated in FIG. 2). The channel region 112 as part of the body region 114 may include a partial compensation by n-type dopants for adjusting the threshold voltage, for example. The partial compensation may be achieved by a tilted ion implantation through a sidewall of a trench, for example. The first gate dielectric layer 1081 of the gate dielectric structure 108 also adjoins to an n⁺-doped source region 116 that is arranged between the p-doped body region 114 and the first surface 1031. The first gate dielectric layer 1081 of the gate dielectric structure 108 further adjoins to an n-doped current spread region 118 that is arranged between the p-doped body region 114 and an n-doped drift region 120. The n-doped drift region 120 has a smaller doping concentration than the current spread region 118. The n-doped drift region 120 is electrically coupled to a second load electrode L2 via the second surface 1032 of the SiC semiconductor body 102.

At a second sidewall 1242 of the gate structure 106, the first dielectric layer 1081 adjoins to a p-doped diode region 123. The p-doped diode region 123 includes a first sub-region 1231 and a second sub-region 1232. Doping concentration profiles of the first and second sub-regions 1231, 1232 overlap one another along a vertical direction y. The number of sub-regions may also differ from the illustrated example of two sub-regions, e.g. be one, three, or four, or five, or even more. An interlayer dielectric 126 electrically isolates the gate electrode structure 110 from the first load electrode L1.

The schematic views of FIGS. 3A to 3C are for illustrating the operation principle of power semiconductor devices configured as n-channel power MOSFETs as described in the examples herein.

Referring to FIG. 3A, the power MOSFET includes the charge storage layer 1085 integrated in the gate structure 106. In a normal operation mode illustrated in FIG. 3B, an electron channel current flow is indicated by circles. The electrons do not reach the charge storage layer 1085. In a short-circuit mode of the power MOSFET illustrated in FIG. 3C, some of the electrons flowing through the channel region reach the charge storage layer 1085 and contribute to a self-triggering turn-off or shutdown of the short circuit.

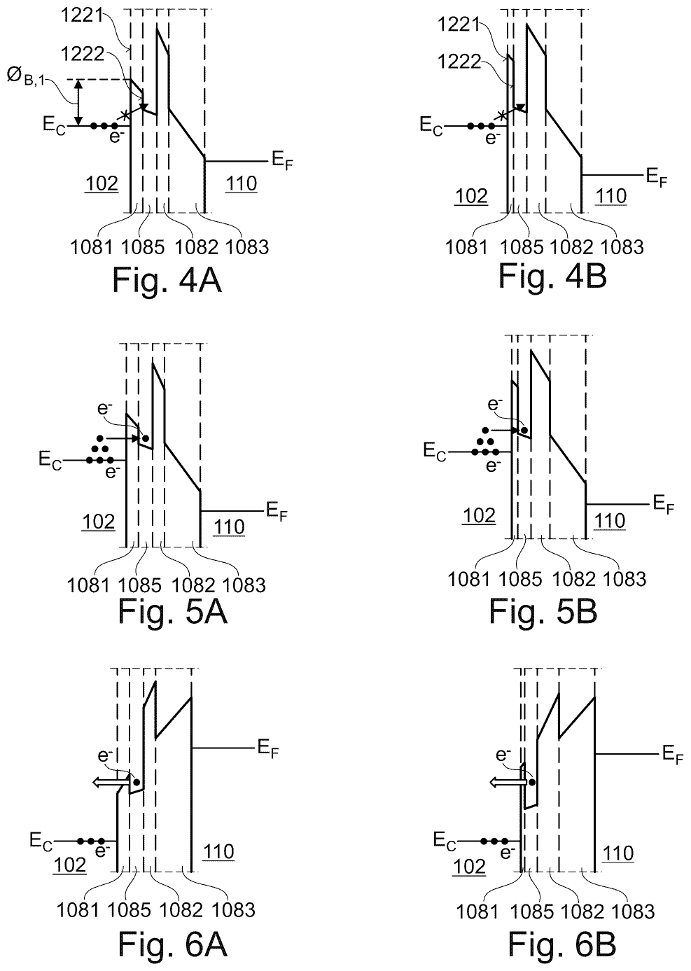

FIGS. 4A and 4B are exemplary conduction band diagrams for illustrating gate dielectric structures 108. The charge storage layer 1085 defines a potential well for electrons and is arranged between the first gate dielectric layer 1081 and the second gate dielectric layer 1082. The gate dielectric structure 108 further includes a third gate dielectric layer 1083 arranged between the second gate dielectric layer 1082 and the gate electrode structure 110. At a first interface 1221 between the SiC semiconductor body 102 and the first gate dielectric layer 1081 a conduction band offset ϕ_{B,1} is present. The schematic conduction band diagrams of FIGS. 4A and 4B differ from one another in that the conduction band offset at a second interface 1222 between the charge storage layer 1085 and the first gate dielectric layer 1081 is smaller in FIG. 4A than in FIG. 4B. This results in a larger asymmetry of the conduction band offsets of the potential well. Moreover, an asymmetry in thickness of the barriers defined by the first gate dielectric layer 1081 and the second gate dielectric layer 1082 is smaller in FIG. 4A than in FIG. 4B. In the normal operation mode illustrated in FIGS. 4A, 4B, electrons in the conduction band Ec of the SiC semiconductor body 102 do not reach the charge storage layer 1085 at low temperatures and positive gate to source voltage.

FIGS. 5A and 5B are exemplary conduction band diagrams that are based on the band diagrams of FIGS. 4A and 4B, respectively, but refer to higher temperatures (e.g. initiated by a short-circuit event). At the higher temperatures, some of the electrons flowing through the channel region reach the charge storage layer 1085 by thermally assisted tunneling (see FIG. 5B) or by thermionic emission (see FIG. 5A) and contribute to a self-triggering turn-off or shutdown of the short circuit.

FIGS. 6A and 6B are exemplary conduction band diagrams that are based on the band diagrams of FIGS. 4A and 4B, respectively, and illustrate a negative gate to source voltage pulse resetting the charge storage layer 1085 of the power MOSFET by transferring the electrons from the charge storage layer 1085 back into the SiC semiconductor body 102 including a Fowler-Nordheim tunneling process (FIG. 6A) and a direct tunneling process (FIG. 6B).

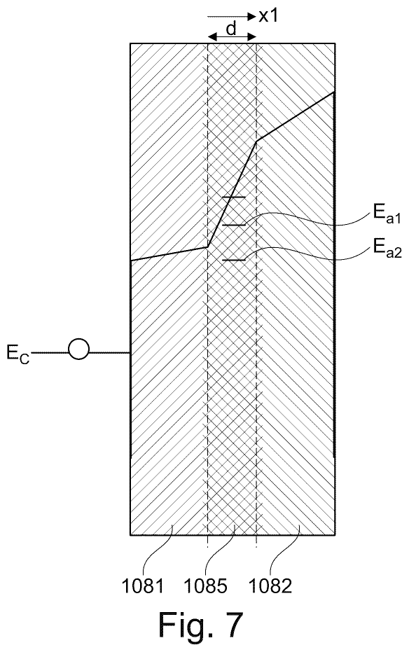

FIG. 7 is an exemplary conduction band diagram for illustrating a gate dielectric structure having a charge storage layer 1085 including a varying material composition. The varying material composition is a transition gate dielectric layer having a material composition that changes, along a thickness direction x1 of the gate dielectric structure 108 over an extent d, from the material composition of the first gate dielectric layer 1081 to the material composition of the second gate dielectric layer 1082. The transition gate dielectric layer includes impurities configured as acceptor-like states within the dielectric bandgap. The acceptor like-states are exemplified by reference numerals Ea1, Ea2 and are larger in energy than the conduction band edge Ec of the SiC semiconductor body. When shrinking the extent d to zero, the acceptor-like states become interface trap states at an interface between the first gate dielectric layer 1081 and the second gate dielectric layer 1082.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the disclosed subject matter. This application is intended to cover any adaptations or variations of the specific embodiments discussed herein. Therefore, it is intended that the disclosed subject matter be limited only by the claims and the equivalents thereof.

1. A power semiconductor device, comprising:
a silicon carbide (SiC) semiconductor body having a first surface and a second surface opposite to the first surface, the SiC semiconductor body comprising a transistor cell area comprising transistor cells, each of the transistor cells comprising
a gate structure comprising a gate dielectric structure and a gate electrode structure on the gate dielectric structure, wherein the gate dielectric structure comprises a first gate dielectric layer adjoining to the SiC semiconductor body, a second gate dielectric layer, and a dielectric charge storage layer arranged between the first gate dielectric layer and the second gate dielectric layer.

2. The power semiconductor device of claim 1, wherein a conduction band offset at a first interface between the SiC semiconductor body and the first dielectric layer has a value in a range from 1.0 eV to 2 eV.

3. The power semiconductor device of claim 1, wherein the gate dielectric structure further comprises a third gate dielectric layer arranged between the second gate dielectric layer and the gate electrode, the third gate dielectric layer adjoining to the gate electrode.

4. The power semiconductor device of claim 3, wherein the third gate dielectric layer is a high-k dielectric layer.

5. The power semiconductor device of claim 1, wherein the second gate dielectric layer adjoins to the gate electrode.

6. The power semiconductor device of claim 1, wherein the dielectric charge storage layer comprises a potential well for electrons, and a conduction band offset at a second interface between the dielectric charge storage layer and the first gate dielectric layer and is smaller than a conduction band offset at a third interface between the dielectric charge storage layer and the second gate dielectric layer.

7. The power semiconductor device of claim 6, wherein a difference between the conduction band offset at the third interface and the conduction band offset at the second interface has a value in a range from 0.5 eV to 3 eV.

8. The power semiconductor device of claim 7, wherein the conduction band offset at the second interface has a value in a range from 0.5 eV to 1.5 eV.

9. The power semiconductor device of claim 1, wherein the dielectric charge storage layer is a Hf₂O₃ layer, the first gate dielectric layer is an Al₂O₃ layer, and the second gate dielectric layer is a SiO₂ layer.

10. The power semiconductor device of claim 1, wherein the dielectric charge storage layer is an interface layer comprising interface trap states at an interface between the first gate dielectric layer and the second gate dielectric layer.

11. The power semiconductor device of claim 1, wherein the dielectric charge storage layer is a transition gate dielectric layer having a material composition that changes, along a thickness direction of the gate dielectric structure, from the material composition of the first gate dielectric layer to the material composition of the second gate dielectric layer.

12. (canceled)

13. (canceled)

14. The power semiconductor device of claim 1, wherein a thickness of the first gate dielectric has a value in a range from 3 nm to 20 nm.

15. The power semiconductor device of claim 1, wherein the power semiconductor device is an n-channel vertical power MOSFET comprising a gate trench comprising the gate structure.

16. The power semiconductor device of claim 15, wherein the vertical power MOSFET comprises a p-doped diode region adjoining to one sidewall of opposite first and second sidewalls of the gate trench, and wherein the p-doped diode region adjoins to a bottom side of the gate trench.

17. A method for operating the power semiconductor device of claim 1, comprising:
resetting the dielectric charge storage layer of the power semiconductor device at least in part by applying a negative gate to source voltage pulse.

18. (canceled)

19. A power semiconductor device, comprising:
a silicon carbide (SiC) semiconductor body having a first surface and a second surface opposite to the first surface, the SiC semiconductor body comprising a transistor cell area comprising transistor cells, each of the transistor cells comprising
a gate structure comprising a gate dielectric structure and a gate electrode structure on the gate dielectric structure, wherein the gate dielectric structure comprises a first gate dielectric layer adjoining to the SiC semiconductor body, a second gate dielectric layer, and a charge storage layer arranged between the first gate dielectric layer and the second gate dielectric layer,
wherein the charge storage layer is an interface layer comprising interface trap states at an interface between the first gate dielectric layer and the second gate dielectric layer.

20. The power semiconductor device of claim 19, wherein a thickness of the first gate dielectric has a value in a range from 3 nm to 20 nm.

21. The power semiconductor device of claim 19, wherein the power semiconductor device is an n-channel vertical power MOSFET comprising a gate trench comprising the gate structure.

22. The power semiconductor device of claim 21, wherein the vertical power MOSFET comprises a p-doped diode region adjoining to one sidewall of opposite first and second sidewalls of the gate trench, and wherein the p-doped diode region adjoins to a bottom side of the gate trench.

23. A method for operating the power semiconductor device of claim 19, comprising:
resetting the dielectric charge storage layer of the power semiconductor device at least in part by applying a negative gate to source voltage pulse.

24. A power semiconductor device, comprising:
a silicon carbide (SiC) semiconductor body having a first surface and a second surface opposite to the first surface, the SiC semiconductor body comprising a transistor cell area comprising transistor cells, each of the transistor cells comprising
a gate structure comprising a gate dielectric structure and a gate electrode structure on the gate dielectric structure, wherein the gate dielectric structure comprises a first gate dielectric layer adjoining to the SiC semiconductor body, a second gate dielectric layer, and a charge storage layer arranged between the first gate dielectric layer and the second gate dielectric layer,
wherein the charge storage layer is a transition gate dielectric layer having a material composition that changes, along a thickness direction of the gate dielectric structure, from the material composition of the first gate dielectric layer to the material composition of the second gate dielectric layer.

25. The power semiconductor device of claim 24, wherein a thickness of the transition gate dielectric layer has a value in a range from 0.1 nm to 3 nm.

26. The power semiconductor device of claim 24, wherein the transition gate dielectric layer comprises a concentration of impurities having a value in a range from 10¹¹ cm⁻³ to 10¹³ cm⁻³.
